(19) United States
(12) Patent Application Publication
(10) Pub. No.: US 2013/0248114 A1
(43) Pub. Date: Sep. 26, 2013

(54) CHIP BONDING APPARATUS

(71) Applicant: SAMSUNG ELECTRONICS CO., LTD., Suwon-si (KR)

(72) Inventors: Seung Dae SEOK, Yingin-si (KR); Kyoungran KIM, Suwon-si (KR); Jae Bong SHIN, Gunpo-si (KR); Hyung Sok YEO, Hwaseong-si (KR); Byung Joon LEE, Yongin-si (KR); Il Young HAN, Euiwang-si (KR)

(73) Assignee: SAMSUNG ELECTRONICS CO., LTD., Suwon-Si (KR)

(21) Appl. No.: 13/826,446

(22) Filed: Mar. 14, 2013

(30) Foreign Application Priority Data
Mar. 22, 2012 (KR) 10-2012-0029299

(51) Int. Cl. H01L 21/683

(52) U.S. Cl. CPC H01L 21/6838
USPC 156/382

(57) ABSTRACT

A bonding apparatus includes at least one stage unit to support a circuit board having a chip thereon and a bonding unit coupled to the stage unit to define a chamber. The bonding unit has at least one inductive heater to heat to bond the chip to the circuit board, and the stage unit includes a vacuum generator configured to generate a vacuum between the stage unit and the circuit board. The vacuum is used to hold the circuit board on the stage unit during bonding of the chip to the circuit board. The induction heater may include one or more induction heating antennas, and the chamber may include one or more stage units.

### CROSS-REFERENCE TO RELATED APPLICATION

This application claims the benefit of Korean Patent Application No. 2012-0029299, filed on Mar. 22, 2012 in the Korean Intellectual Property Office, the disclosure of which is incorporated herein by reference in its entirety.

### BACKGROUND

1. Field

The present disclosure relates to semiconductor devices.

2. Description of the Related Art

Wire bonding methods typically use metal wires made of fine gold or aluminum to connect and bond Integrated Circuit (IC) chips to circuit boards. These methods allow metal pads serving as input/output terminals to be formed only at edges of IC chips. Therefore, implementing these methods may be difficult when the number of input/output terminals increases and distances between the terminals decrease due to higher density of IC chips. Additionally, deterioration of electric properties may occur due to generation of noise in bonded wires as a signal frequency increases. Instead of wire bonding methods, flip-chip bonding methods have been used in which solder bumps are formed at a rear surface of an IC chip and are fused to a circuit board via reflow to bond the IC chip to the circuit board.

In some flip-chip bonding methods, after an IC chip having solder bumps is aligned with a metal pad on a circuit board, both the IC chip and the circuit board are heated above a melting point of the solder bumps. The heating may be performed by infrared heating, convection heating, or the like, for the purpose of bonding the solder bumps of the IC chip to the metal pad of the circuit board via reflow, i.e. melting of the solder bumps.

However, bonding methods using infrared or convection heating may cause damage to polymer circuit boards because they are heated with the IC chip to a temperature in a range of 200° C.-300° C. for reflow of the solder bumps.

A different type of flip-chip bonding method using inductive heating may be adopted because they rapidly and selectively raise a temperature of a board within a short time and, thus, may prevent deterioration of IC chips and circuit boards and reduce process time.

In the case of the flip-chip bonding methods using inductive heating, in consideration of the fact that a temperature of a board rapidly increases within a short time, a vacuum generation device may be used to fix a board to a stage in order to prevent deformation of the board due to rapid temperature change.

Such a vacuum generation device is typically installed separately from and is connected to the stage using a connection pipe through which fluid flows. If a large capacity of compressed air is supplied to the vacuum generation device, vacuum is generated between the stage and the circuit board via the connection pipe, whereby the circuit board is fixed to the stage.

However, in the above-described configuration, an additional facility to supply a large capacity of compressed air to the vacuum generation device may be used and an additional space for installation of the vacuum generation device may be required. Further, loss of vacuum in the connection pipe between the stage and the vacuum generation device may result in poor vacuum generation efficiency.

### SUMMARY

One or more embodiments described herein correspond to a chip bonding apparatus which may efficiently fix a circuit board to a stage by generating vacuum between the circuit board and the stage.

In accordance with one embodiment, a chip bonding apparatus includes at least one stage unit to support a circuit board having a chip placed thereon, and a bonding unit coupled to the stage unit to define a chamber, the bonding unit including an inductive heating antenna to generate a high frequency within the chamber to bond the chip to the circuit board, wherein the stage unit includes a vacuum generator to generate vacuum between the stage unit and the circuit board to fix the circuit board onto the stage unit upon bonding of the chip to the circuit board.

The stage unit may include at least one stage to support the circuit board seated thereon, a base arranged below the stage to support the stage, at least one fluid supply pipe to supply a fluid into the stage, and at least one fluid discharge pipe to discharge the fluid supplied into the stage, and the vacuum generator may be inserted in the stage.

The stage may include a plurality of absorption holes formed in an upper surface thereof, on which the circuit board is seated, for vacuum absorption of the circuit board, a first flow-path communicating with the fluid supply pipe, and a second flow-path communicating with the fluid discharge pipe.

The vacuum generator may include a fluid suction portion communicating with the first flow-path, through which the fluid is suctioned so as to be supplied to the first flow-path, a fluid discharge portion communicating with the second flow-path, through which the fluid suctioned through the fluid suction portion is discharged, a connecting portion to connect the fluid suction portion and the fluid discharge portion to each other, and a guide portion communicating with the absorption holes and the connecting portion, the guide portion serving to guide the fluid introduced through the absorption holes to the connecting portion by a pressure difference generated as the fluid suctioned through the fluid suction portion flows to the fluid discharge portion.

The stage may further include a third flow-path communicating with the absorption holes and the guide portion.

The chip bonding apparatus may further include a fluid circulation pipe communicating with the fluid discharge pipe and the interior of the chamber to supply the fluid discharged through the fluid discharge portion into the chamber. The fluid may be nitrogen (N2) gas.

In accordance with another embodiment, a chip bonding apparatus includes a chamber, the interior of which is hermetically sealed, at least one stage arranged within the chamber and configured to support a circuit board having a chip placed thereon, an inductive heating antenna arranged above the stage and serving to generate a high frequency within the chamber to bond the chip to the circuit board, and a vacuum generator coupled to the stage and serving to generate a vacuum between the stage and circuit board to fix the circuit board on the stage.

The stage may include an absorber panel to support the circuit board seated thereon and having a plurality of absorption holes for vacuum absorption of the circuit board, and a flow-path defining panel coupled to a lower surface of the absorber panel to define a flow-path communicating with the absorption holes.

The vacuum generator may be provided in the flow-path defining panel and communicates with the absorption holes and the flow-path.

The chip bonding apparatus may further include a fluid circulation pipe to supply the gas used for generation of vacuum in the vacuum generator into the chamber.

In accordance with another embodiment, a chip bonding apparatus includes at least one stage unit configured to support a circuit board having a chip thereon and a bonding unit coupled to the stage unit to define a chamber, the bonding unit including at least one inductive heater configured to heat to bond the chip to the circuit board, and the stage unit including a vacuum generator configured to generate a vacuum between the stage unit and the circuit board to hold the circuit board onto the stage unit during bonding of the chip to the circuit board.

The stage unit may include at least one stage to support the circuit board thereon, a base arranged below the stage to support the stage, at least one fluid supply pipe to supply a fluid into the stage, and at least one fluid discharge pipe to discharge the fluid supplied into the stage, wherein the vacuum generator is in the stage.

The stage may include an upper surface including a plurality of absorption holes, the circuit board overlaps the plurality of absorption holes, a first flow-path communicates with the at least one fluid supply pipe, and a second flow-path communicates with the at least one fluid discharge pipe.

The vacuum generator may include a fluid suction portion communicating with the first flow-path, through which the fluid is suctioned so as to be supplied to the first flow-path; a fluid discharge portion communicating with the second flow-path, through which the fluid suctioned through the fluid suction portion is discharged; a connecting portion to connect the fluid suction portion and the fluid discharge portion to each other; and a guide portion communicating with the absorption holes and the connecting portion, the guide portion serving to guide the fluid introduced through the absorption holes to the connecting portion by a pressure difference generated as the fluid suctioned through the fluid suction portion flows to the fluid discharge portion. The stage may also include a third flow-path communicating with the absorption holes and the guide portion.

The apparatus may include a fluid circulation pipe communicating with the fluid discharge pipe and the interior of the chamber to supply the fluid discharged through the fluid discharge portion into the chamber. The fluid includes nitrogen (N₂) gas.

In accordance with another embodiment, a processing apparatus comprises a stage to support an object and a vacuum generator in the stage, the stage including a plurality of first holes coupled to the vacuum generator and a plurality of second holes adjacent the first holes and configured to receive a gas, a first pressure applied through the first holes to hold the object and a second pressure applied through the second holes to receive the gas during a time when the first pressure is not applied through the first holes.

The apparatus may include an inductive heater configured to heat the object when held by the first pressure on the stage, and a spacer to separate the inductive heater and stage by a distance. The spacer may be made of a material which does not exhibit eddy current when a field is applied.

Additionally, the first holes are at a first location which overlaps the object and the second holes are at a second location which does not overlap the object. The first holes may be between at least two of the second holes. Also, a section of the stage that includes the first holes may be made from a material that dissipates heat at a faster rate than a material from which the object is made.

In accordance with another embodiment, chip bonding apparatus comprises a chamber; a stage configured to support a circuit board having a chip thereon, the stage located in the chamber; an inductive heater configured to generate heat to bond the chip to the circuit board; and a vacuum generator coupled to the stage and configured to generate a vacuum between the stage and the circuit board to hold the circuit board on the stage. The vacuum generator may be located in or coupled to the stage. When coupled to the stage, a vacuum source for the vacuum generator may located inside or outside the chamber.

The stage may include an absorber to support the circuit board, the absorber including a plurality of holes transfer the vacuum absorption to the circuit board; and a flow-path between the vacuum generator and the holes in the absorber. Also, a fluid circulation pipe may be included to supply a gas used for generation of the vacuum in the chamber. The gas may include a nitrogen (N₂) gas or another processing gas.

### BRIEF DESCRIPTION OF THE DRAWINGS

The above and other features and advantages of example embodiments will become more apparent by describing in detail example embodiments with reference to the attached drawings. The accompanying drawings are intended to depict example embodiments and should not be interpreted to limit the intended scope of the claims. The accompanying drawings are not to be considered as drawn to scale unless explicitly noted.

FIG. 1 shows one embodiment of a chip and circuit board.

FIG. 2 shows one embodiment of a chip bonding apparatus.

FIG. 3 shows a front view of the chip bonding apparatus.

FIGS. 4 and 5 show examples of a stage unit in this apparatus.

FIG. 6 shows an example of a bonding unit.

FIG. 7 shows an inductive heating antenna in the bonding unit.

FIG. 8 shows an interior arrangement of a chamber.

### DETAILED DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (eg., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

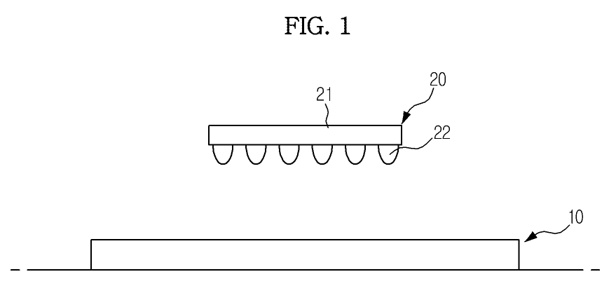

FIG. 1 shows one embodiment of a flip chip 20 and a circuit board 10. The flip chip 20 includes a die 21 which, for example, may be in the form of a flat plate and a plurality of solder bumps 22 protruding from one surface of the die 21 to mount the die 21 to a circuit board 10.

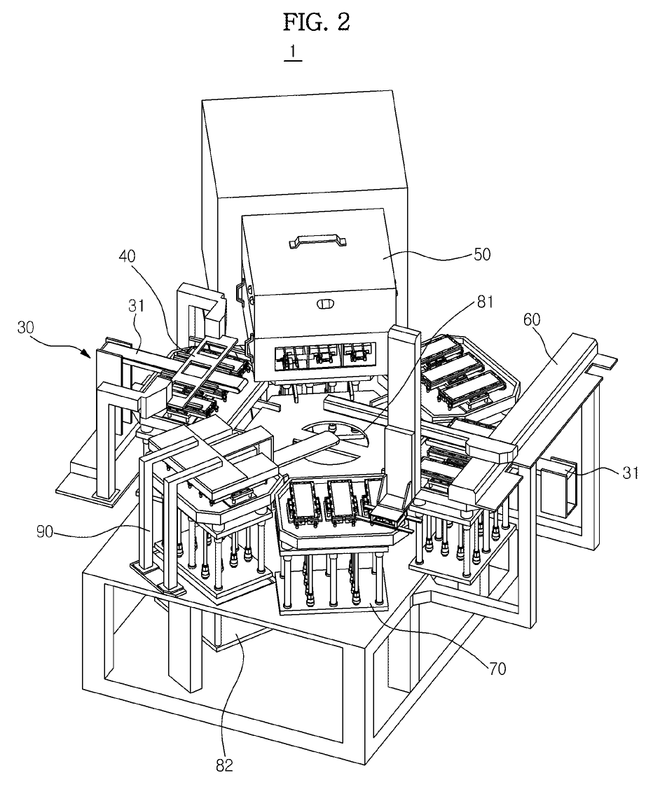

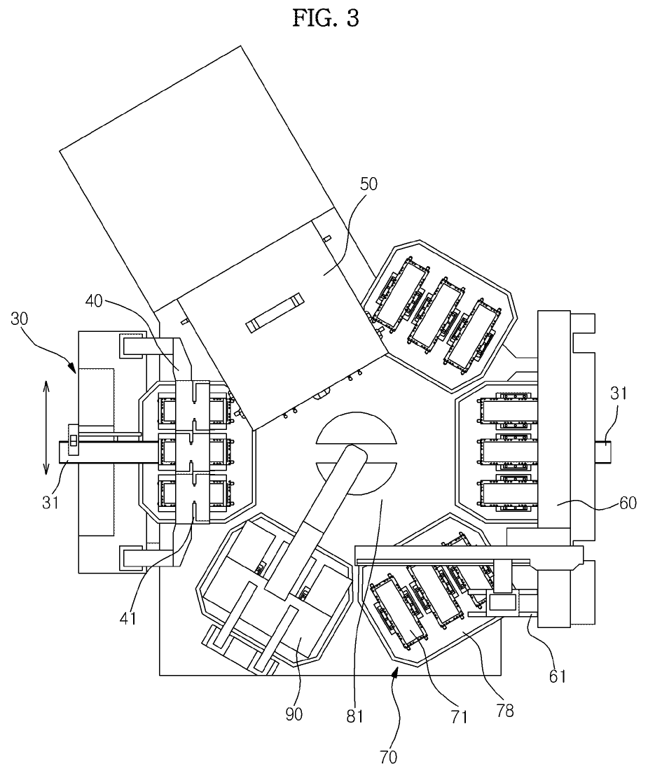

FIG. 2 shows one embodiment of a chip bonding apparatus, and FIG. 3 shows a top view of the chip bonding apparatus. As illustrated in FIGS. 2 and 3, the chip bonding apparatus, designated by reference numeral 1, includes a transfer unit 30, a stage unit 70, a loading unit 40, a bonding unit 50, an unloading unit 60, a cooling unit 90, and a rotating unit 81.

The transfer unit 30 transfers the circuit board 10 having the flip chip 20 placed thereon to a bonding unit 50 and also discharges the completely bonded circuit board 10 to an external location.

The stage unit 70 has a stage onto which the circuit board 10 having the flip chip 20 placed thereon is loaded.

The loading unit 40 holds the circuit board 10 transferred via the transfer unit 30 and thereafter loads the circuit board 10 on the stage unit 70.

The bonding unit 50 bonds the flip chip 20 to the circuit board 10.

The unloading unit 60 separates the completely bonded circuit board 10 from stage unit 70 and delivers the circuit board 10 to the transfer unit 30 that discharges the circuit board 10 to an external location.

The cooling unit 90 reduces a temperature of heated stage unit 70.

The rotating unit 81 rotates stage unit 70 by a predetermined angle.

Operation of the transfer unit 30 will now be explained in greater detail. In accordance with one embodiment, the transfer unit 30 includes a conveyor 31 to transfer the circuit board 10 having the flip chip 20 placed thereon, and a motor (not shown) to move the conveyor 31 leftward or rightward. The loading unit 40 may include a plurality of holders 41 arranged in parallel to hold the circuit board 10 delivered from the transfer unit 30.

Once the circuit board 10 having the flip chip 20 placed thereon has been placed on the conveyor 31, the conveyor 31 is driven to deliver the circuit board 10 to one of the plurality of holders 41 of the loading unit 40. After the circuit board 10 is delivered to one of the plurality of holders 41 arranged in parallel, the transfer unit 30 moves the conveyor 31 to deliver another circuit board 10 to the next holder 41.

Once the circuit boards 10 have been delivered to all the holders 41 of the loading unit 40 and the stage unit 70 onto which the circuit boards 10 will be loaded has been moved to a position corresponding to the loading unit 40, the holders 41 of the loading unit 40 place the circuit boards 10 on the stage unit 70.

Additionally, the transfer unit 30 may be divided into a supply unit to deliver the circuit board 10 having the flip chip 20 placed thereon to the loading unit 40 via the conveyor 31 as described above and a discharge unit to discharge the completely bonded circuit board 10. The discharge unit may discharge the circuit board 10 to an external location from the bonding apparatus via operation of the conveyor 31, once the completely bonded circuit board 10 has been placed on the conveyor 31 by the unloading unit 60.

Instead of conveyor 31, the transfer unit may use another transfer device to supply the circuit board 10 to the bonding apparatus and to discharge the completely bonded circuit board 10 from the bonding apparatus for progress of a next process.

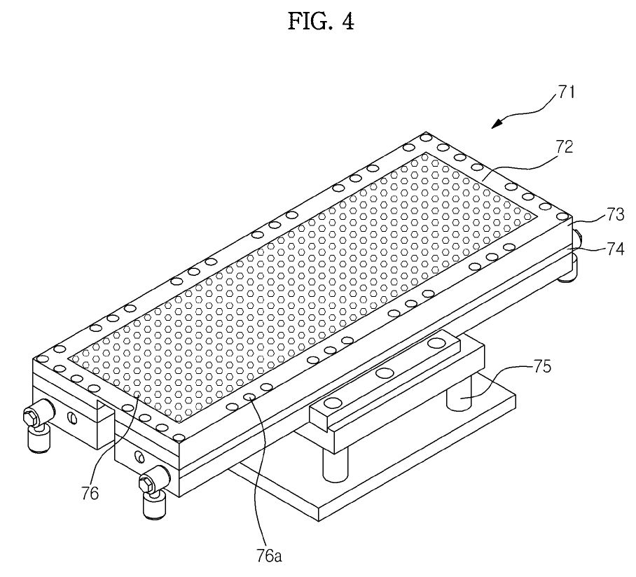

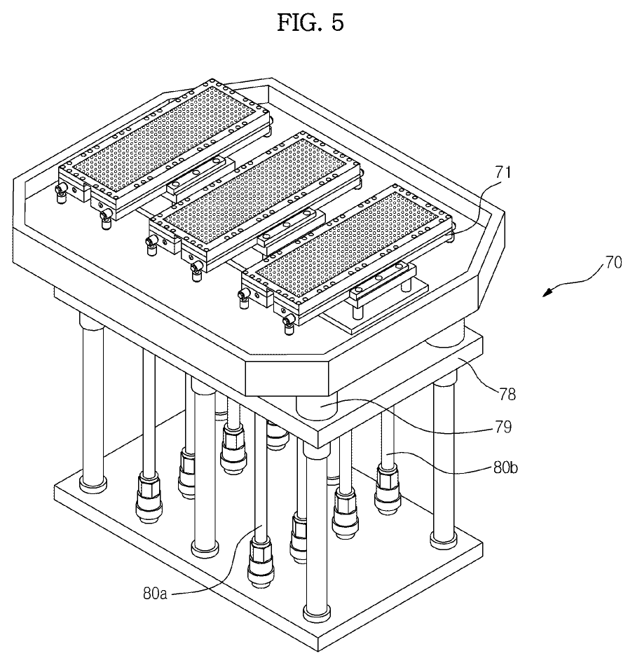

FIGS. 4 and 5 show an embodiment of stage unit 70 of the chip bonding apparatus, on which stage unit is loaded circuit board 10 by the loading unit 40. In this embodiment, the stage unit 70 includes a plurality of stages 71 on which circuit boards 10 are placed respectively, a base 78 configured to support the plurality of stages 71, and fluid supply pipes 80a and fluid discharge pipes 80b to respectively supply or discharge a fluid.

Each stage 71 includes an absorber panel 72 configured to support the circuit board 10 placed thereon, a flow-path defining panel 73 configured to support the absorber panel 72 and having a variety of flow-paths, and a thermally insulating panel 74 to prevent heat transfer.

A plurality of absorption holes 76 and exhaust holes 76a are formed in a surface of the absorber panel 72. The absorption holes 76 are connected to a vacuum generator 100 provided within the stage 71 to perform vacuum chucking.

If bonding is performed in a state in which the circuit board 10 is not fixed on the stage 71, serious deformation of the circuit board 10 may occur due to rapid temperature increase during bonding and even the deformed board may come into contact with an inductive heating antenna 52 of the bonding apparatus, causing generation of arcing. Moreover, local burning of the circuit board 10 may occur and/or flight of the flip chips 20 placed on the circuit board 10 may occur.

In accordance with one embodiment, absorption holes 76 are formed in the absorber panel 72 to fix the circuit board 10 to the absorber panel 72 via vacuum absorption, which may prevent, for example, bending of the heated circuit board 10. The exhaust holes 76a suction and exhaust a gas (e.g., nitrogen gas) supplied into a chamber 150 to remove the gas (e.g., nitrogen) from within the chamber atmosphere.

The absorption holes 76 may be formed in a central region of the absorber panel 72 on which the circuit board 10 is placed, and the exhaust holes 76a may be formed in a rim region of the absorber panel 72.

Meanwhile, the absorber panel 72 may be formed, for example, of Invar as an alloy of nickel (Ni) and iron (Fe), graphite, silicon carbide (SiC), or the like. Heat generated from solder bumps 22 during bonding is rapidly transferred to the relatively cold board that comes into contact with the solder bumps 22, which may disable electrical connection of contacts. For this reason, the absorber panel 72 may be formed of Invar, graphite, SiC or the like that exhibits excellent heat dissipation and high deformation resistance.

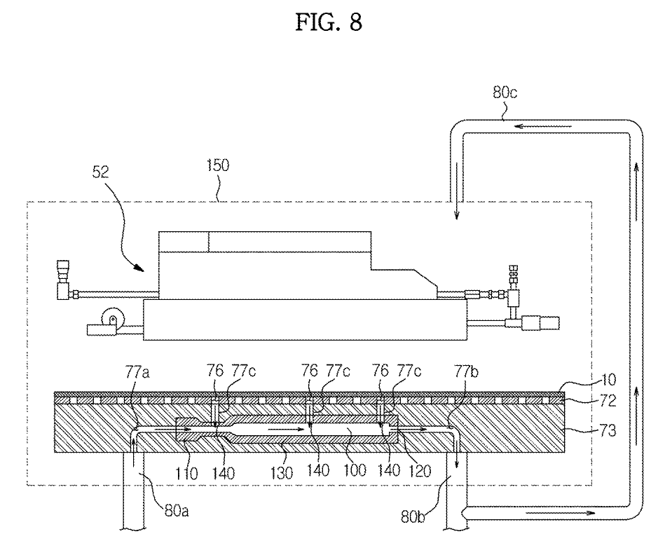

The flow-path defining panel 73 is installed to a lower surface of the absorber panel 72 to support the absorber panel 72 and includes flow-paths 77a, 77b and 77c communicating with the plurality of absorption holes 76 of the absorber panel 72 and vacuum generator 100, as shown, for example, in FIG. 8.

The thermally insulating panel 74 is installed below a lower surface of the flow-path defining panel 73 to prevent heat generated during bonding from dissipating outward via the stage 71, thereby preventing deterioration in melting efficiency of the solder bumps 22.

An elastic structure 75 is installed below a lower surface of the stage 71. The elastic structure 75 is deformed upon receiving external force and is returned to an original shape thereof when the force is removed. The elastic structure 75 may, for example, be a spring.

When the stage unit 70 on which the circuit board 10 has been loaded is moved upward to a position spaced apart from the inductive heating antenna 52 of the bonding unit 50 by a certain distance, the stage unit 70 is additionally moved upward to hermetically seal the bonding unit 50.

Through the additional upward movement of the stage unit 70, the base 78 of the stage unit 70 is closely fitted into a bottom opening of the bonding unit 50 to hermetically seal the bonding unit 50. Additional upward movement force applied to the stage unit 70 to hermetically seal the bonding unit 50 is transmitted to the elastic structure 75, causing the elastic structure 75 to be compressed. The stage unit 70 is moved upward in proportion to a compressed degree of the elastic structure 75.

The additional upward movement of the stage unit 70 to hermetically seal the bonding unit 50 is accomplished via compression of the elastic structure 75, and may have no influence on a constant distance between the inductive heating antenna 52 and the stage 71 that is maintained by a spacer 55 for uniform bonding.

The base 78 to support the stage 71 is installed below a lower surface of the stage 71. The base 78 may be designed to have the same shape and area as the bottom opening of the bonding unit 50. Thereby, when the stage unit 70 is moved upward, the base 78 of the stage unit 70 may be closely fitted into the bottom opening of the bonding unit 50. In other embodiments, the base may have a shape and/or area different from the shape and area of the bottom opening of the bonding unit.

After the base 78 of the stage unit 70 has closely been fitted into the bottom opening of the bonding unit 50, the bonding unit 50 is hermetically sealed. An elastic structure 79 may be installed to a lower surface of the base 78 and may perform the same function as the elastic structure 75 installed to the lower surface of the stage 71. Additionally, the elastic structure 79 may enable upward or downward tilting of the base 78, which provides some movement margin of the base 78.

The fluid supply pipes 80a and the fluid exhaust pipes 80b to supply or exhaust a fluid are coupled to the lower surface of the base 78. The fluid supplied into the stage 71 through the fluid supply pipes 80a passes through the vacuum generator 100 and is discharged outward from the chamber (150, see FIG. 8) through the fluid exhaust pipes 80b.

In one embodiment, a plurality of stage units 70 is installed on the rotating unit 81 and is spaced apart from one another. Thereby, the stage units 70 are subjected to predetermined respective processes via rotation of rotating unit 81.

The stage unit 70 may be vertically moved by a vertical drive unit 82 which, for example, may include a transfer screw installed to a lower surface of the rotating unit 81 and a motor. As such, a distance between the circuit board 10 loaded on the stage 71 and the inductive heating antenna 52 of the bonding unit 50 may be adjusted.

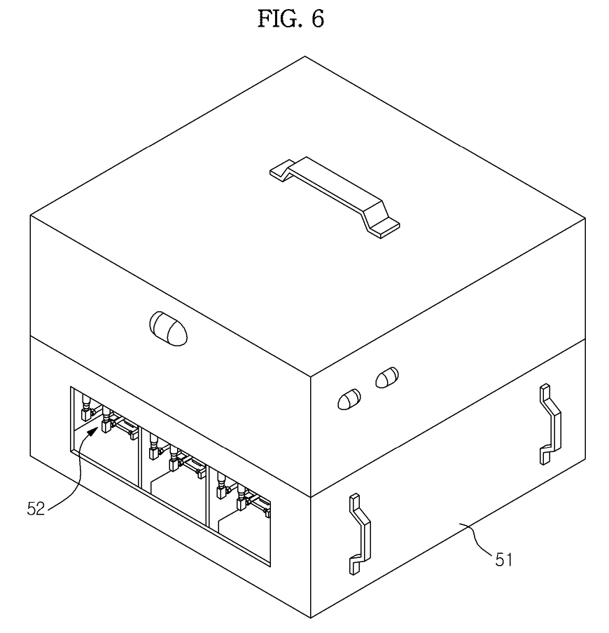

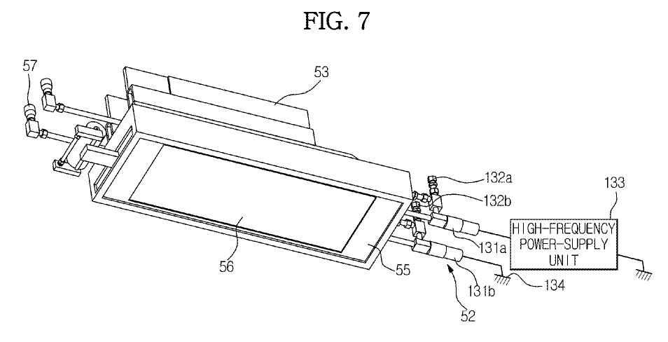

FIG. 6 shows another view of the bonding unit, and FIG. 7 shows one arrangement of the inductive heating antenna of the bonding unit. As shown, the bonding unit 50 includes a housing 51 and a plurality of inductive heating antennas 52 arranged within the housing 51. The bonding unit 50 includes the housing 51 to shield electromagnetic waves, and the housing 51 has an open bottom.

When the stage unit 70 is moved upwardly through the open bottom of the housing 51 until the base 78 of the stage unit 70 is closely fitted into the open bottom of the housing 51, the housing 51 is hermetically sealed to define the chamber 150. Once the chamber 150 has been defined, the solder bumps 22 of the flip chip 20 are heated to a molten state to bond the flip chip 20 to circuit board 10 by inductive heating using one or more of the inductive heating antennas 52 provided for the chamber 150.

The inductive heating antennas 52 are arranged within the housing 51 to perform inductive heating on the flip chip 20 so as to bond the flip chip 20 to the circuit board 10. In one embodiment, the inductive heating antennas 52 are mounted to an inner ceiling surface of the housing 51 via support pieces 53. A plurality of support pieces 53 may be provided to ensure sufficiently stable fixing of the inductive heating antennas 52.

The spacer 55 may be mounted to a lower surface of the inductive heating antenna 52. The spacer 55 may maintain a constant distance between the stage 71 and the inductive heating antenna 52 when the stage 71 on which the circuit board 10 has been loaded approaches the inductive heating antenna 52 for bonding.

The spacer 55 may be formed of a material that does not transmit an eddy current created by a magnetic field around the inductive heating antenna 52 and is not deformed at high temperatures. For example, the spacer 55 may be formed of ceramic or engineering plastic that may endure high temperatures. The spacer 55 may be designed such that a cross-sectional width thereof is equal to a distance between the inductive heating antenna 52 and the circuit board 10 that is required for efficient and uniform bonding of the circuit board 10.

An anti-pollution plate 56 may be mounted to the lower surface of the inductive heating antenna 52. The anti-pollution plate 56 prevents flux evaporated during bonding from being attached to the inductive heating antenna 52, thereby preventing pollution of the inductive heating antenna 52.

The inductive heating antenna 52 may further include a plurality of connection terminals 131a and 131b for connection of a high-frequency power-supply unit 133 and a ground 134. The connection terminals 131a and 131b may be cylindrical terminals located at one side of the inductive heating antenna 52.

The high-frequency power-supply unit 133 includes a high-frequency generator to generate high-frequency AC power of 27.12 MHz or 13.56 MHz, and a matcher to match impedances between the high-frequency generator and the inductive heating antenna 52.

The inductive heating antenna 52 may further include cooling water ports 132a and 132b to cool the inductive heating antenna 52 heated via supply of high-frequency AC power. The cooling water ports 132a and 132b include inlet and outlet ports connected to cooling lines 57 for supply of cooling water.

When high-frequency AC power is applied to the inductive heating antenna 52, a magnetic field is created around the inductive heating antenna 52. In this case, if a metal is present near the inductive heating antenna 52, an eddy current flows through the metal by the created magnetic field and inductive heating of the metal occurs based on the eddy current.

Accordingly, when circuit board 10 on which the flip chip 20 is placed is arranged below the inductive heating antenna 52 and high-frequency AC power is applied to the inductive heating antenna 52, an AC magnetic field is created around the inductive heating antenna 52. As an eddy current is applied to the solder bumps 22 by the AC magnetic field, the solder bumps 22 are heated by the eddy current and, as a result, the flip chip 20 is attached to the circuit board 10.

FIG. 8 shows one possible arrangement for an interior of the chamber. As shown, the chamber 150 is defined via coupling of the bonding unit 50 and the stage unit 70 and bonding to fix the flip chip 20 to the circuit board 10 is performed.

In the chamber, it may be necessary to fix the circuit board 10 to the stage 71 in order to prevent deformation of the circuit board 10, generation of arcing, and/or flight of the flip chips 20 during the bonding. To this end, the stage unit 70 may be equipped to include the vacuum generator 100 to realize vacuum absorption of the circuit board 10 to the stage 71, and the flow-paths 77a, 77b and 77c communicating with the vacuum generator 100 and the plurality of absorption holes 76.

The vacuum generator 100 is located within the stage 71 and, more particularly, within the flow-path defining panel 73 constituting the stage 71. The vacuum generator 10 includes a fluid suction portion 110 for suction of a fluid into the stage 71, a fluid discharge portion 120 for discharge of the fluid suctioned through the fluid suction portion 110, a connecting portion 130 between the fluid suction portion 110 and the fluid discharge portion 120, and a guide portion 140 for communication between the plurality of absorption holes 76 and the connecting portion 130.

The fluid suction portion 110 communicates with the first flow-path 77a that will be described hereinafter. As a fluid is suctioned into the fluid suction portion 110 through the fluid supply pipe 80a and the first flow-path 77a, the fluid flows to the connecting portion 130 and the fluid discharge portion 120. The fluid suction portion 110 may be provided, for example, with a solenoid valve to adjust the flow rate of fluid supplied to the fluid suction portion 110.

The fluid discharge portion 120 discharges not only a fluid suctioned from the fluid suction portion 110 and having passed through the connecting portion 130, but also air or gas introduced into a gap between circuit board 10 and absorber panel 72 through the guide portion 140. This air or gas may be introduced through guide portion 140 as a result of negative pressure generated during flow of the fluid through the connecting portion 130, outwardly from the stage 70.

The connecting portion 130 connects the fluid suction portion 110 and the fluid discharge portion 120 to each other to allow the fluid suctioned through the fluid suction portion 110 to be discharged through the fluid discharge portion 120. During flow of the suctioned fluid, negative pressure is created in the connecting portion 130 and the air between the circuit board 10 and the absorber panel 72 is introduced into the connecting portion 130 through the plurality of absorption holes 76 and the guide portion 140. As vacuum is created between the circuit board 10 and the absorber panel 72, force to absorb and fix the circuit board 10 to the absorber panel 72 is generated.

The guide portion 140 guides the air, introduced through the plurality of absorption holes 76 by negative pressure created in the connecting portion 130, to the connecting portion 130.

The flow-paths 77a, 77b and 77c communicate with the vacuum generator 100 and the plurality of absorption holes 76. In accordance with one embodiment, flow-path 77a is connected between the fluid supply pipe 80a and the fluid suction portion 110 to allow a fluid supplied into the stage 71 through the fluid supply pipe 80a to be suctioned by the vacuum generator 100. Flow-path 77b is connected between fluid discharge portion 120 and fluid exhaust pipe 80b to allow the fluid discharged from the vacuum generator 100 to be discharged outward from the stage 71. Flow-path 77c is connected between the plurality of absorption holes 76 and guide portion 140 to allow air between the circuit board 10 and the absorber panel 72 to be introduced into the vacuum generator 100.

To ensure absorption and fixing of the circuit board 10 to the stage 71, the fluid supplied to the vacuum generator 100 may be nitrogen (N2) gas to process the solder bumps 22 for connection between the circuit board 10 and the flip chip 20. In another embodiment, a different gas or fluid may be used.

The solder bumps 22 of the flip chip 20 that come into contact with the circuit board 10 may be subjected to chemical treatment using flux. This flux may correspond to a solvent for surface treatment of a metal to prevent a molten metal surface from being oxidized via reaction with the atmosphere. Because adhesion may be difficult if an oxide layer is formed via oxidation of a molten metal surface during bonding of a metal, this flux treatment may be performed to prevent oxidation of the molten metal surface.

During this treatment, evaporation of flux may occur during bonding at a high temperature and bonding may fail due to oxidation of the solder bumps 22 that come into contact with the board. To prevent oxidation of the solder bumps 22, a nitrogen (or other gas) atmosphere may be formed within the chamber 150 to enable flux treatment.

The nitrogen gas is suctioned into the vacuum generator 100 through the fluid supply pipe 80a and first flow-path 77a and then is discharged outwardly from stage 71 through flow-path 77b and fluid exhaust pipe 80b. Thereafter, the fluid is supplied into the chamber 150 through the fluid exhaust pipe 80a and a fluid circulation pipe 80c which communicate with the chamber 150.

That is, as the nitrogen gas is introduced into the stage 71 and flows through the vacuum generator 100 by suction force of the vacuum generator 100, the circuit board 10 is fixed to the stage 71. Thereafter, the fluid is supplied into the chamber 150 through the fluid exhaust pipe 80b and fluid circulation pipe 80c for flux treatment. Finally, the nitrogen gas used for flux treatment is discharged outward from the chamber 150 through the exhaust holes 76a.

By directly coupling the vacuum generator 100 to the stage 71, enhanced absorption efficiency is achieved. Further, using nitrogen gas for use in bonding as a fluid to generate suction force in the vacuum generator 100 may eliminate a facility to supply a large capacity of compressed air, which may result in cost reduction and enhanced productivity.

The cooling unit 90 cools the stage unit 70 from which all the completely bonded circuit boards 10 have been unloaded. After completion of bonding and cooling, stage 71 of the stage unit 70 from which the circuit board 10 has been removed has a high temperature of approximately 100° C.

If the circuit board 10 having the flip chip 20 placed thereon is again loaded above the stage 71 without lowering the temperature of the stage 71 to approximately 60° C. or less, the high temperature of the stage 71 may cause deformation of the circuit board 10. Therefore, cooling unit 90 to lower the temperature of the stage 71 may be used to lower the temperature of the stage before another circuit board is loaded.

In one embodiment, the cooling unit 90 may include a plurality of chambers containing cooling water. The chambers may be designed to have approximately the same shape as that of the stages 71, and the number of the chambers may be equal to the number of stages 71. However, the configuration of the cooling unit 90 is not limited to the above description, and the cooling unit 90 may be replaced by any other shapes and configurations so long as they function to cool the stages 71. A temperature of the cooling water may be, for example, approximately 20° C.

The stage unit 70, from which the circuit board 10 has been unloaded, is moved to a position where the cooling unit 90 is installed via rotation of the rotating unit 81. The stage unit 70 moved to the installation position of the cooling unit 90 is moved upward to the cooling unit 90 until it comes into contact with the cooling unit 90. The upward movement of the stage unit 70 stops upon coming into contact with the cooling unit 90.

The stage unit 70 in contact with the cooling unit 90 as described above performs heat exchange with the cooling water of the cooling unit 90, thereby being cooled. This state is continued until the temperature of the stage unit 70 is lowered to a predetermined temperature or less.

The rotating unit 81 includes a rotatable plate on which the stage unit 70 is installed, and a motor to drive the rotatable plate. The rotatable plate may have any one of a number of geometrical shapes including but not limited to a circular or polygonal shape.

The plurality of stage units 70 may be installed on the rotating plate. Although the number of the stage units 70 installed on the rotating plate is not limited, it will be appreciated that six stage units 70 may be installed on the rotating plate in one embodiment. The rotating plate may have a plurality of sections, for example, equal in number to the number of the stage units 70 such that the stage units 70 are installed to the respective sections in a one to one ratio.

The transfer unit 30, loading unit 40, bonding unit 50, unloading unit 60, and cooling unit 90 may be installed respectively at predetermined positions on the rotating plate.

The rotating unit 81 is rotated by a split angle equivalent to the number of the stage units 70 after a predetermined time for each process has passed. For example, if six stage units 70 are installed, the rotating unit 81 is rotated by 60 degrees at a time.

The unloading unit 60 unloads the circuit board 10, which has been completely bonded in the bonding unit 50 and has been subjected to the cooling process, from the stage unit 70. The unloading unit 60 may include a pickup member 61 to pickup the circuit board 10 and movable arms that are movable respectively in X-axis, Y-axis and Z-axis to position the pickup member 61 above the circuit board 10 that will be unloaded.

The pickup member 61 is rotatably installed to a distal end of the arm that is movable in the Z-axis. That is, the pickup member 61 is positioned above the circuit board 10 to be unloaded via movement of the arms movable on the respective axes. Then, the pickup member 61 is rotated to have a shape coincident with the circuit board 10 to pickup the circuit board 10. The unloaded circuit board 10 is placed on the conveyor 31 of the discharge unit constituting the transfer unit 30 and is discharged outward from the bonding apparatus via the conveyor 31.

According to one or more embodiments, a vacuum generator is therefore provided which generates vacuum between a stage and a circuit board for using in fixing or otherwise holding and supporting the circuit board to the stage. The circuit board may, therefore, be directly coupled to the stage, which eliminates the use of a connection pipe between the stage and the vacuum generator and prevents possible loss in the connection pipe, resulting in enhanced vacuum generation efficiency.

Further, enhanced installation convenience is accomplished because a space for installation of the vacuum generator may be unnecessary.

Further, by using a gas during bonding as a fluid to generate vacuum in the vacuum generator, it may be unnecessary for a facility to supply a large capacity of compressed air and cost reduction and enhanced productivity may be accomplished.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A chip bonding apparatus comprising:
at least one stage unit configured to support a circuit board having a chip thereon; and
a bonding unit coupled to the stage unit to define a chamber,
the bonding unit including at least one inductive heater configured to heat to bond the chip to the circuit board, and the stage unit including a vacuum generator configured to generate a vacuum between the stage unit and the circuit board to hold the circuit board onto the stage unit during bonding of the chip to the circuit board.

2. The apparatus according to claim 1, wherein the stage unit includes:
at least one stage to support the circuit board thereon;
a base arranged below the stage to support the stage;
at least one fluid supply pipe to supply a fluid into the stage; and
at least one fluid discharge pipe to discharge the fluid supplied into the stage, wherein the vacuum generator is in the stage.

3. The apparatus according to claim 2, wherein the stage includes an upper surface including a plurality of absorption holes, the circuit board overlaps the plurality of absorption holes, a first flow-path communicates with the at least one fluid supply pipe, and a second flow-path communicates with the at least one fluid discharge pipe.

4. The apparatus according to claim 3, wherein the vacuum generator includes:
a fluid suction portion communicating with the first flow-path, through which the fluid is suctioned so as to be supplied to the first flow-path;
a fluid discharge portion communicating with the second flow-path, through which the fluid suctioned through the fluid suction portion is discharged;
a connecting portion to connect the fluid suction portion and the fluid discharge portion to each other; and
a guide portion communicating with the absorption holes and the connecting portion, the guide portion serving to guide the fluid introduced through the absorption holes to the connecting portion by a pressure difference generated as the fluid suctioned through the fluid suction portion flows to the fluid discharge portion.

5. The apparatus according to claim 4, wherein the stage further includes a third flow-path communicating with the absorption holes and the guide portion.

6. The apparatus according to claim 5, further comprising
a fluid circulation pipe communicating with the fluid discharge pipe and the interior of the chamber to supply the fluid discharged through the fluid discharge portion into the chamber.

7. The apparatus according to claim 2, wherein the fluid includes nitrogen (N₂) gas.

8. A processing apparatus comprising:
a stage to support an object; and
a vacuum generator in the stage,
the stage including a plurality of first holes coupled to the vacuum generator and a plurality of second holes adjacent the first holes, the plurality of second holes configured to receive a gas, the first holes configured allowing a first pressure to be applied to hold the object and the second holes allowing a second pressure to be applied to receive the gas during a time when the first holes do not apply the first pressure.

9. The apparatus according to claim 8, further comprising:
an inductive heater configured to heat the object when held by the first pressure on the stage.

10. The apparatus according to claim 9, further comprising
a spacer to separate the inductive heater and stage by a distance.

11. The apparatus according to claim 10, wherein the spacer is made of a material which does not exhibit eddy current when a field is applied.

12. The apparatus according to claim 8, wherein
the first holes are at a first location which overlaps the object, and
the second holes are at a second location which does not overlap the object.

13. The apparatus according to claim 8, wherein the first holes are between at least two of the second holes.

14. The apparatus according to claim 8, wherein a section of the stage that includes the first holes is made from a material that dissipates heat at a faster rate than a material from which the object is made.

15. A chip bonding apparatus comprising:
a chamber;
a stage configured to support a circuit board having a chip thereon, the stage located in the chamber;
an inductive heater configured to generate heat to bond the chip to the circuit board; and
a vacuum generator coupled to the stage and configured to generate a vacuum between the stage and the circuit board to hold the circuit board on the stage.

16. The apparatus according to claim 15, wherein the vacuum generator is located in the stage.

17. The apparatus according to claim 15, wherein the stage includes:
an absorber to support the circuit board, the absorber including a plurality of holes transfer the vacuum absorption to the circuit board; and
a flow-path between the vacuum generator and the holes in the absorber.

18. The apparatus according to claim 17, further comprising
a fluid circulation pipe to supply a gas used for generation of the vacuum in the chamber.

19. The apparatus according to claim 18, wherein the gas includes a nitrogen (N₂) gas.

20. A chamber comprising the processing apparatus according to claim 8.
